(19) United States
(12) Patent Application Publication
(10) Pub. No.: US 2013/0161783 A1
(43) Pub. Date: Jun. 27, 2013

(54) SEMICONDUCTOR DEVICE INCLUDING ISOLATION LAYER AND METHOD FOR FABRICATING THE SAME

(71) Applicants: Jeong-Seob OH, Gyeonggi-do (KR); Young-Soo Ahn, Gyeonggi-do (KR)

(72) Inventors: Jeong-Seob OH, Gyeonggi-do (KR); Young-Soo Ahn, Gyeonggi-do (KR)

(21) Appl. No.: 13/605,874

(22) Filed: Sep. 6, 2012

(30) Foreign Application Priority Data
Dec. 21, 2011 (KR) 10-2011-0139637

(51) Int. Cl. H01L 21/762; H01L 29/06

(52) U.S. Cl. 257/510; 438/437; 257/E29.02; 257/E21.546

(57) ABSTRACT

A semiconductor device includes an isolation trench formed in a semiconductor substrate; an isolation layer filling the isolation trench; and a first epitaxial layer interposed between the isolation layer and the semiconductor substrate, wherein a lattice structure of the semiconductor substrate has an angle difference from a lattice structure of the first epitaxial layer adjacent to the semiconductor substrate.

### CROSS-REFERENCE TO RELATED APPLICATIONS

The present application claims priority of Korean Patent Application No. 10-2011-0139637, filed on Dec. 21, 2011, which is incorporated herein by reference in its entirety.

### BACKGROUND

1. Field

Exemplary embodiments of the present invention relate to a semiconductor technology, and more particularly, to a semiconductor device including an isolation layer and a method for fabricating the semiconductor device.

2. Description of the Related Art

A semiconductor device includes an isolation layer for electrically isolating internal devices from one another. The isolation layer is generally formed through a Shallow Trench Isolation (STI) process. In the STI process, isolation trenches are formed by etching a substrate which is formed of a semiconductor material, such as silicon, in a given depth and then an isolation layer is formed by filling the isolation trenches with a dielectric material.

A high-density plasma (HDP) oxide layer is usually used as an isolation layer, but as the aspect ratio of isolation trenches increases due to improvement in the integration degree of a semiconductor device, a semiconductor device reaches a limit in filling isolation trenches with an HDP oxide layer.

To overcome the limitation, a fluidic insulation layer is widely used. The fluidic insulation layer is of a material that has a relatively low viscosity so as to flow along the surface of the isolation trench. For example, the fluidic insulation layer may be a perhydro-polysilazane (PSZ) layer, and the fluidic insulation layer may be formed through a spin coating process.

A thermal treatment may be performed after the isolation trenches are filled with the fluidic insulation layer. The thermal treatment is performed in order to discharge gas contents from the fluidic insulation layer and obtain a dense isolation layer. For example, a perhydro-polysilazane (PSZ) layer may be formed in the isolation trenches through a spin coating process and then a silicon oxide (SiO₂) isolation layer may be formed by densifying it through a thermal treatment.

When the isolation layer is formed of the fluidic insulation layer, there are problems as follows.

However, when the isolation layer is formed of the fluidic insulation layer and the thermal treatment is carried out after the formation of the fluidic insulation layer, thermal stress is caused during the thermal treatment. The thermal stress may dislocate active regions, thereby causing a defect in the active regions. For example, a leakage path may be formed in the active regions so as to deteriorate the reliability of a semiconductor device.

Moreover, the gas discharge during the thermal treatment performed onto the fluidic insulation layer decreases the volume of the finally produced isolation layer, which is the silicon oxide (SiO₂) isolation layer. Therefore, voids may be formed in the finally produced isolation layer. The voids formed in a relatively upper portion of the isolation layer also function as a leakage path, deteriorating the reliability of the semiconductor device.

### SUMMARY

Exemplary embodiments of the present invention are directed to a semiconductor device including an isolation layer that may improve the reliability of the semiconductor device, and a method for fabricating the semiconductor device.

In accordance with an exemplary embodiment of the present invention, a semiconductor device includes an isolation trench formed in a semiconductor substrate; an isolation layer filling the isolation trench; and a first epitaxial layer interposed between the isolation layer and the semiconductor substrate, wherein a lattice structure of the semiconductor substrate has an angle difference from a lattice structure of the first epitaxial layer adjacent to the semiconductor substrate.

In accordance with another exemplary embodiment of the present invention, a method for fabricating a semiconductor device includes forming an isolation trench by selectively etching a semiconductor substrate; forming a first epitaxial layer on internal walls of the isolation trench; and forming an isolation layer filling the isolation trench, wherein a lattice structure of the semiconductor substrate has an angle difference from a lattice structure of the first epitaxial layer adjacent to the semiconductor substrate.

### BRIEF DESCRIPTION OF THE DRAWINGS

FIG. 1 is a cross-sectional view illustrating a semiconductor device in accordance with an exemplary embodiment of the present invention.

FIG. 2 is a cross-sectional view illustrating a lattice structure of an A part of the semiconductor device shown in FIG. 1.

FIG. 3 is a flowchart describing a method for fabricating a semiconductor device in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

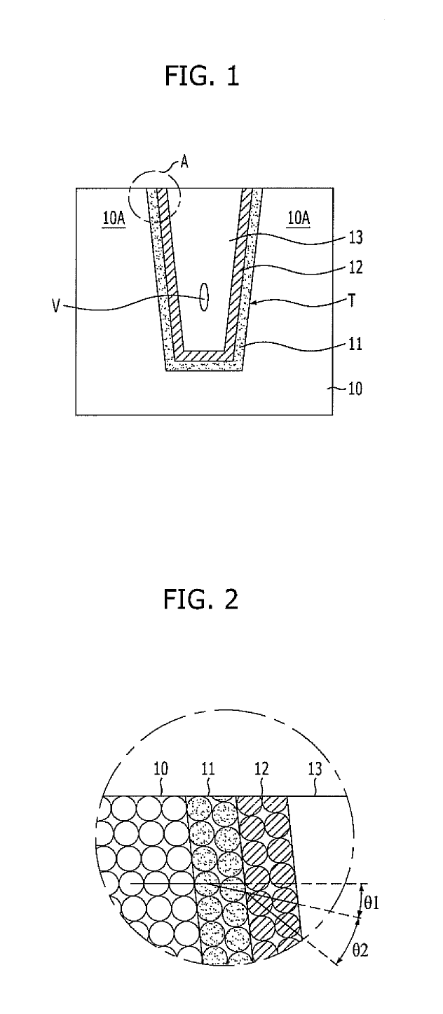

Hereinafter, a semiconductor device in accordance with an embodiment of the present invention is described with reference to FIGS. 1 and 2. FIG. 1 is a cross-sectional view illustrating a semiconductor device in accordance with an exemplary embodiment of the present invention. Particularly, FIG. 1 shows the portion of an isolation layer. FIG. 2 is a cross-sectional view illustrating a lattice structure of an A part of the semiconductor device shown in FIG. 1.

Referring to FIG. 1, the semiconductor device in accordance with the exemplary embodiment of the present invention includes an isolation trench T for defining active regions 10A in a semiconductor substrate 10, at least two epitaxial layers 11 and 12, e.g., a first epitaxial layer 11 and a second epitaxial layer 12, that are formed along the internal walls of the isolation trench T, and an isolation layer 13 for filling the isolation trench T where, for example, the first and second epitaxial layers 11 and 12 are formed.

The semiconductor substrate 10 may be a silicon substrate, but the scope of the present invention is not limited to it.

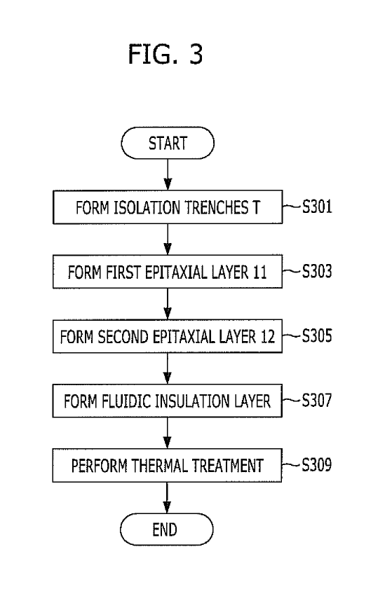

The isolation layer 13 is formed of an insulation material. For example, the isolation layer 13 may be an oxide layer, e.g., a silicon oxide (SiO₂) layer. The isolation layer 13 may be the oxide layer formed by performing the a thermal treatment on a fluidic insulation layer, e.g., a perhydro-polysilazane (PSZ) layer, and the isolation layer 13 may include a void V that is formed during the thermal treatment, which is to be described in detail with reference to FIG. 3.

The first and second epitaxial layers 11 and 12 are interposed between the isolation layer 13 and the semiconductor substrate 10, and it may alleviate the thermal stress that is caused during the formation of the isolation layer 13 and/or control the location of the void V. This embodiment of the present invention shows two epitaxial layers 11 and 12, but the scope of the present invention is not limited to it and there may be more than three epitaxial layers in the isolation trench T. The first and second epitaxial layers 11 and 12 are described below with reference to FIG. 2.

Referring to FIG. 2, each of the semiconductor substrate 10, the first epitaxial layer 11, and the second epitaxial layer 12 has a lattice structure where a plurality of constituents are stacked in three dimensions.

In the lattice structure, there is lattice mismatch between the semiconductor substrate 10 and the first epitaxial layer 11 that are disposed adjacent to each other. In other words, the lattice structure of the semiconductor substrate 10 mismatches that of the first epitaxial layer 11. For example, the lattice structure of the first epitaxial layer 11 may have an angle difference 01 from the lattice structure of the semiconductor substrate 10 in one dimension.

Similarly, there is lattice mismatch between the first epitaxial layer 11 and the second epitaxial layer 12 that are disposed adjacent to each other. For example, the lattice structure of the second epitaxial layer 12 may have an angle difference 02 from the lattice structure of the first epitaxial layer 11 in one dimension.

As described above, when there are lattice mismatches between the semiconductor substrate 10 and the first epitaxial layer 11 and between the first epitaxial layer 11 and the second epitaxial layer 12, the same effect as the thermal stress caused during the formation of the isolation layer 13 is decreased is obtained. To be specific, the thermal stress is transferred to the active regions 10A through the first and second epitaxial layers 11 and 12. In the course of the transfer of the thermal stress, the Mean Free Path (MFP) is elongated due to the difference in the angles of the lattice structures, and the dimension of the transferred thermal stress is decreased due to the lattice mismatches. As a result, the active regions 10A may be protected from being dislocated and the defect originating from the dislocation of the active regions 10A may be suppressed.

Furthermore, a material having a similar lattice structure to that of the semiconductor substrate 10, for example, a material of an element of the same group or a material having a similar lattice constant, may be used as the first epitaxial layer 11. Also, a material having a similar lattice structure to that of a fluidic insulation layer for forming the first epitaxial layer 11 and the isolation layer 13 may be used as the second epitaxial layer 12. In this case, since the first epitaxial layer 11 has similar strain relaxation characteristics to those of the semiconductor substrate 10 and the second epitaxial layer 12, the first epitaxial layer 11 may function as a sort of a buffer between them. Since the second epitaxial layer 12 has similar strain relaxation characteristics to those of the first epitaxial layer 11 and the fluidic insulation layer, the second epitaxial layer 12 may function as a sort of a buffer between them. For example, when the semiconductor substrate 10 is a silicon substrate, the first epitaxial layer 11 may be a Ge layer or an YSZ layer (Yttria Stabilized Zirconia), and the second epitaxial layer 12 may be an InP, CdS, ZnSe, ZnS, MgS, AIP, GaP, or CeO₂ layer. Furthermore, insulation characteristics may be increased by using a material having a relatively high band gap energy as the first and second epitaxial layers 11 and 12.

Meanwhile, the location of the void V formed in the isolation layer 13 may be controlled by adjusting the thickness of the first and second epitaxial layers 11 and 12 and/or the lattice structure angle differences θ1+θ2 based on the semiconductor substrate 10.

To be specific, as the first and second epitaxial layers 11 and 12 are thicker and thicker, the width of the isolation trench T becomes narrower. Therefore, the fluidic insulation layer may not be fully buried in the lower portion of the isolation trench T, thus increasing the probability of forming the void V. Therefore, if the thicknesses of the first and second epitaxial layers 11 and 12 are increased within such a range that desired device characteristics are satisfied, the void V may be formed in the relatively lower portion of the isolation trench T.

Also, if the lattice structure angle difference 01 between the semiconductor substrate 10 and the first epitaxial layer 11 and/or the lattice structure angle difference θ1+θ2 between the semiconductor substrate 10 and the second epitaxial layer 12 is/are increased, the downward strength applied to the void V may be increased, thus disposing the void V in the relatively lower portion.

Hereinafter, a method for fabricating the semiconductor device shown in FIGS. 1 and 2 is described with reference to FIG. 3. FIG. 3 is a flowchart describing a method for fabricating a semiconductor device in accordance with an embodiment of the present invention.

Referring to FIG. 3, a semiconductor substrate 10, e.g., a silicon substrate, is provided and then an isolation trench T is formed by selectively etching isolation regions of the semiconductor substrate 10 in step S301.

Subsequently, a first epitaxial layer 11 is formed on the internal walls of the isolation trench T by performing a first epitaxial growth process in step S303. The first epitaxial growth process may be a Low-Pressure Chemical Vapor Deposition (LPCVD) process and it may be performed under the pressure of hundreds of mTorr at a temperature of hundreds of ° C. until the thickness of the first epitaxial layer 11 becomes several Å.

Although not illustrated in the drawing, after the process of step S303, a given treatment may be performed on the surface of the first epitaxial layer 11. For example, the treatment may be a Light-Etch Treatment or an oxygen (O₂) treatment and the treatment increases the roughness of the first epitaxial layer so as to increase the adhesiveness thereof to a second epitaxial layer 12, which is to be formed later.

Subsequently, a second epitaxial growth process is performed to form a second epitaxial layer 12 over the first epitaxial layer 11 in step S305. The second epitaxial growth process may be performed similarly to the first epitaxial growth process. Also, although not illustrated in the drawing, after the second epitaxial growth process is performed, a given treatment may be performed on the surface of the second epitaxial layer 12 to increase the roughness of the second epitaxial layer 12.

Subsequently, a fluidic insulation layer is formed to fill the isolation trench T including the second epitaxial layer 12 in step S307. The fluidic insulation layer may be a perhydro-polysilazane (PSZ) layer, and it may be formed though a spin coating process.

Subsequently, a thermal treatment is performed on the fluidic insulation layer in step S309. As a result of the thermal treatment, the fluidic insulation layer is densified to become an isolation layer 13. Even though the thermal treatment is performed, the presence of the first and second epitaxial layers 11 and 12 decreases the thermal stress applied to the active regions 10A of the semiconductor substrate 10.

The semiconductor device including an isolation layer and a fabrication method thereof in accordance with an embodiment of the present invention may improve the reliability of the semiconductor device.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
an isolation trench formed in a semiconductor substrate;
an isolation layer filling the isolation trench; and
a first epitaxial layer interposed between the isolation layer and the semiconductor substrate,
wherein a lattice structure of the semiconductor substrate has an angle difference from a lattice structure of the first epitaxial layer adjacent to the semiconductor substrate.

2. The semiconductor substrate of claim 1, further comprising:
a second epitaxial layer interposed between the first epitaxial layer and the isolation layer, wherein a lattice structure of the second epitaxial layer has an angle difference from the lattice structure of the first epitaxial layer adjacent to the second epitaxial layer.

3. The semiconductor substrate of claim 2, wherein the isolation layer includes a position adjustable void.

4. The semiconductor substrate of claim 2, wherein the angle difference between the lattice structures of the semiconductor substrate and the first epitaxial layer is smaller than that of the semiconductor substrate and the second epitaxial layer.

5. The semiconductor substrate of claim 3, wherein the position adjustable void is formed in different portions inside the isolation layer depending on angle difference between lattice structures of the semiconductor substrate and the epitaxial layers.

6. The semiconductor substrate of claim 3, wherein the position adjustable void is formed in different portions inside the isolation layer depending on the thickness of the epitaxial layers.

7. A method for fabricating a semiconductor device, comprising:
forming an isolation trench by selectively etching a semiconductor substrate;
forming a first epitaxial layer on internal walls of the isolation trench; and
forming an isolation layer filling the isolation trench,
wherein a lattice structure of the semiconductor substrate has an angle difference from a lattice structure of the first epitaxial layer adjacent to the semiconductor substrate.

8. The method of claim 7, further comprising:
forming a second epitaxial layer on the first epitaxial layer,
wherein a lattice structure of the second epitaxial layer has an angle difference from the lattice structure of the first epitaxial layer adjacent to the second epitaxial layer.

9. The method of claim 7, wherein the forming of the isolation layer comprises:
forming a fluidic insulation layer; and
performing a thermal treatment on the fluidic insulation layer.

10. The method of claim 7, wherein in the forming of the isolation layer, the isolation layer includes a position adjustable void.

11. The method of claim 8, further comprising:
performing a surface treatment after forming the first epitaxial layer and after forming the second epitaxial layer, respectively.

12. The method of claim 8, wherein the angle difference between the lattice structures of the semiconductor substrate and the first epitaxial layer is smaller than that of the semiconductor substrate and the second epitaxial layer.

13. The method of claim 10, wherein a location of the void inside the isolation layer is controlled based on angle difference between lattice structures of the semiconductor substrate and the epitaxial layers.

14. The method of claim 10, wherein a location of the void inside the isolation layer is controlled based on the thickness of the epitaxial layers.
